(19) United States
(12) Patent Application Publication
(10) Pub. No.: US 2016/0103192 A1
(43) Pub. Date: Apr. 14, 2016

(54) SENSOR DEVICE FOR DIRECT MAGNETIC FIELD IMAGING

(71) Applicant: YEDA RESEARCH AND DEVELOPMENT CO. LTD., Rehovot (IL)

(72) Inventors: Jonathan REINER, Jonathan (IL); Lior EMBON, Rehovot (IL); Yonathan ANAHORY, Rehovot (IL); Yuri MYASOEDOV, Rehovot (IL); Eli ZELDOV, Rehovot (IL)

(21) Appl. No.: 14/893,085

(22) PCT Filed: May 20, 2014
(86) PCT No.: PCT/IL2014/050441

§ 371 Date: Nov. 23, 2015

Related U.S. Application Data
(60) Provisional application No. 61/826,725, filed on May 23, 2013.

(51) Int. Cl. G01R 33/035; G01R 33/00

(52) U.S. Cl. CPC G01R 33/0354; G01R 33/0052

(57) ABSTRACT

The present invention discloses a sensor device comprising a probe carrying a three-dimensional magnetic field sensor. The probe has a conical tip portion with an edge being configured as the three-dimensional magnetic field sensor. The sensor at the edge of the tip comprises at least three Josephson junctions, each junction being formed of a superconducting layer interrupted by a barrier. The barrier comprises a non-superconducting layer or a geometrical constriction. The conical tip portion of the probe forms a tapered three-dimensional structure having at least one arc-like part crossing the opening of the tip portion such that the apex has a closed-loop basis and a plurality of complimentary spaced-apart facets defined by the at least one arc, thereby enabling measurement of both in-plane and out-of-plane magnetic fields separately.

### TECHNOLOGICAL FIELD

This invention relates to local magnetic field sensor devices for direct magnetic field vector imaging.

### REFERENCES

References considered to be relevant as background to the presently disclosed subject matter are listed below:
[1] A. Finkler, Y. Segev, Y. Myasoedov, M. L. Rappaport, L. Ne'eman, D. Vasyukov, E. Zeldov, M. E. Huber, J. Martin, and A. Yacoby. Self-aligned nanoscale squid on a tip. Nano letters, 10(3):1046-1049, 2010.
[2] A. Finkler, D. Vasyukov, Y. Segev, L. Ne'eman, E O Lachman, M L Rappaport, Y. Myasoedov, E. Zeldov, and ME Huber. Scanning superconducting quantum interference device on a tip for magnetic imaging of nanoscale phenomena. Review of Scientific Instruments, 83(7):073702-073702, 2012.
[3] D. L. Tilbrook. Nanosquid sensitivity for isolated dipoles and small spin populations. Superconductor Science and Technology, 22(6):064003, 2009.
[4] E. Zeldov, J. R. Clem, M. McElfresh, and M. Darwin. Magnetization and transport currents in thin superconducting films. Physical Review B, 49:9802-9822, 1994.

Acknowledgement of the above references herein is not to be inferred as meaning that these are in any way relevant to the patentability of the presently disclosed subject matter.

### BACKGROUND OF THE INVENTION

Rich and diverse research on nanoscale physics has given rise to exploration of many interesting phenomena where magnetic interactions play an important role. This creates a need for precise and versatile magnetic characterization, promoting the development of magnetic imaging techniques that concentrate on imaging small magnetic moments with high spatial resolution.

Besides Nuclear magnetic resonance (NMR), common local magnetic imaging methods include scanning Hall probes, scanning Superconducting Quantum Interference Devices (SQUIDs), Magnetic Force Microscopy (MFM), Lorentz microscopy, Bitter decoration, and Magneto-optical imaging. Lorentz microscopy and MFM have a high spatial resolution (10 to 100 nm); however their field sensitivity is relatively low (of the order of 10 Gauss). Scanning SQUID microscopy has the highest field sensitivity but it has a rather poor spatial resolution (of several microns).

The operating principle of a SQUID is based on two properties unique to superconductivity: Cooper pair tunneling between weakly coupled superconductors, known as the Josephson Effect, and magnetic flux quantization in a superconducting ring. In such a device, a dissipationless supercurrent I can flow until it reaches a critical value Ic, where the system switches to a resistive state. The Ic is a smooth and periodic function of magnetic flux Φ threading the SQUID or its pick-up loop. The measurement of Ic is a direct and precise measurement of the magnetic flux in the loop.

Scanning SQUID Microscopy (SSM), as well as the other scanning probe magnetic imaging techniques, is predominately sensitive to the magnetic field component that is normal to the scanning plane. In several applications such as the study of local transport currents distribution in complex samples, current-carrying edge states, transport in surface states, spin polarized currents, imaging of spin accumulation in spintronics devices, and detection of single spins with in-plane polarization, the in-plane component of the magnetic field provides the more local and essential information.

Some of the inventors of the present patent application have developed a novel device and method for fabrication of nano-SQUIDs on the apex of quartz tips that eliminates the need for complex lithography processes. This allows approaching, with the probe, to within several nanometers above the scanning surface. The device and method are described in US publication number 2010/207622 which share the assignee of the present patent application, and which are also described in [1, 2]. The above mentioned devices demonstrated a record sensitivity to small magnetic moments.

### General Description

The present invention discloses a novel sensor device based on a nanoscale multi junction SQUID fabricated on the edge of a sharp tip in a three dimensional geometric configuration. It should be noted that in the present invention the junctions forming the SQUID are fabricated at the end of the tip (also called the apex or the edge of the tip), allowing its unique proximity to the scanned surface. By using this configuration, the magnetic sensor device performs direct magnetic field imaging, with high spatial resolution. By using a tip as a probe which directly approaches the sample, instead of a planar substrate, the distance between the sensor and the sample is minimized, enhancing resolution and accuracy.

The effective spatial resolution of magnetic sensors is determined not only by the size of the sensors, but also by their proximity to the sample. The novel geometrical configuration of the sensor device enables to measure both the in-plane and the out-of-plane components of the magnetic field with remarkable sensitivity. It should be clarified that conventional nanoscale SQUIDs and other common magnetic probe techniques are predominantly sensitive only to the field component which is perpendicular to the scanning plane, or rarely and inaccurately to the out of the sample's plane. Sensitivity of the novel sensor device of the present invention can be tuned so that the observed response comes from either one of those orthogonal components, or from their combination. This is achieved by a proper tuning of the voltage on the SQUID and by applying external magnetic fields. Sensitivity to both in-plane and out-of-plane fields is due to the SQUID's three-dimensional structure, which can be obtained in a specific and non-limiting example by focused ion beam milling. The capability to measure in-plane field enables the use of this novel sensor device in such applications where the signal contribution due to the in-plane field is advantageous, such as in-plane spin detection and transport current distribution in complex systems, as will be detailed further below with respect to FIGS. 3a-3b.

According to the teachings of the present invention, a sensor device comprising a probe carrying a three-dimensional magnetic field sensor is provided. The probe has a conical tip portion with an edge being configured as the three-dimensional magnetic field sensor. The probe when in operation directly approaches a surface of a sample. The sensor at the edge of the tip comprises at least three Josephson junctions, each junction being formed by a superconducting layer and separated by a barrier. The barrier comprises a non-superconducting layer or a geometrical constriction. The conical tip portion of the probe forms a tapered three-dimensional structure having at least one arc-like part crossing the opening of the tip portion such that the apex has a closed-loop basis and a plurality of complimentary spaced-apart facets defined by the at least one arc, thereby enabling measurement of both in-plane and out-of-plane magnetic fields separately. In this connection, it should be understood that the novel geometrical configuration of the conical tip portion defines a plurality of complimentary spaced-apart facets aligned so that each will have an area projected both in the in-plane and out-of-plane direction with respect to the sample. This configuration enables flux coupling from both orthogonal components of the magnetic field and allows their independent measurement. This configuration may be obtained by a built-in separation barrier passing along the tube that defines the spaced-apart regions and by making the arc-like part at the end of the separation barrier protruding forward from the conical tip portion.

In some embodiments, the sensor is configured as a Josephson junction based sensor.

In some embodiments, the sensor comprises a SQUID (Superconducting Quantum Interference Device) loop extending along a circumferential region at the edge of the conical tip portion.

In some embodiments, the edge of the conical tip portion is tapered with a defined tapering angle.

In some embodiments, the conical tip portion is configured such that the arc-like part protrudes forward towards the surface of the sample with respect to side junctions that reside along the closed-loop basis.

In some embodiments, the sensor has one arc-like part crossing the opening of the tip portion forming a double-loop structure such that the edge has two facets and the cross-section of the edge forms a θ-shape with V-shaped profile, hence forming a three-dimensional structure. In this configuration, the junctions are located as follows: one on the central arc-like part and two along the circumference.

In other embodiments, the sensor has two arc-like parts crossing the opening of the tip portion such that the edge has four facets forming a three-dimensional square pyramid shape.

In other embodiments, the sensor has three arc-like parts crossing the opening of the tip portion such that the edge has three facets forming a three-dimensional tetrahedron structure.

In some embodiments, the conical tip portion has a maximal outer diameter not exceeding a few hundreds of nanometers.

In some embodiments, the sensor has a core made from a non-superconducting material and a superconducting layer coating at least one selected circumferential region of the non-superconducting core forming a plurality of Josephson junctions or geometrical constrictions constituting a multi junction SQUID structure.

In some embodiments, the core is made of an electrical insulator material.

In some embodiments, the superconducting layer is made from aluminum niobium, lead, indium, or tin-based materials.

The three-dimensional sensor device may be integrated into a scanning microscope to provide magnetic imaging.

There is also provided a method for fabricating a three-dimensional sensor device. The method comprises heating and pulling a tube to sub-micron dimensions to create a structure having at least one arc-like part crossing the opening of the tube such that the edge of the tube has a closed-loop basis; and milling the edge of the tube to a three-dimensional configuration such that the arc-like part protrudes forward towards a surface of a sample with respect to the side junctions that reside along the closed-loop basis.

In some embodiments, the method comprises evaporating at least two contacts made by any electrically conducting material along the tube by using a mask configured to prevent an electrical short between the contacts.

In some embodiments, the method comprises milling the edge of the tube to a V-shape.

In some embodiments, milling the edge of the tube comprises cutting the edge of the tube at different angles obtained by rotation of the tube about its own axis to form a shape having multiple facets in different orientations at the edge of the tube.

In some embodiments, the milling of the edge is carried out by using a focused ion beam (FIB).

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIGS. 1a-1d represent different possible cross sections of the tip of the three-dimensional sensor device present invention;

FIGS. 2a-2c are scanning electron microscope (SEM) images of a tapered 0-tip;

FIG. 3 is a schematic diagram of a three-step deposition scheme applied to fabricate the three-dimensional sensor device of the present invention;

FIGS. 4a-4b represent calculated flux coupled to a three-dimensional double-loop sensor device with respect to a planar double-loop sensor due to an in-plane oriented electronic spin (3a) and transport current in a superconducting slab (3b), as a function of horizontal distance;

FIG. 5 is a schematic of the measurement circuit (inset) and several current-voltage (IV) curves using the three-dimensional sensor device of the present invention;

FIG. 6 is a schematic view of a SQUID Microscope assembly to be used with the three-dimensional sensor device of the present invention;

FIGS. 7a-7f represent interference patterns of a non-limiting example of the sensor device of the present invention. In particular, FIG. 7a and FIG. 7d are measurement and simulation of Ic(Bₓ,B_{z}) of the sensor device of FIG. 2b respectively; FIG. 7b and FIG. 7e are measurement and simulation of Ic(Bₓ,B_{z}) of FIG. 2c respectively; FIG. 7c is a FFT of FIG. 7b; FIG. 7f is a FFT of FIG. 7e;

FIG. 8 is a field noise spectrum at the working point sensitive to the in-plane and out-of-plane field for a non-limiting example of the sensor device of the present invention at 4.2 K;

FIGS. 9a-9h are images of a wire; in particular FIG. 9a is a SEM image of a 0.35×4 μm′ Pb wire. FIGS. 9b-9h are scanning microscopy images of a non-limiting example of the sensor of the present invention; in particular FIG. 9b shows the profiles of the field measured across a linecut; FIG. 9c and FIG. 9d are DC and AC signals at an Bₓ sensitive point (Bₓ=320 G, B_{z}=0 G), when the sample is in the complete Meissner state respectively; FIG. 9e and FIG. 9f are DC and AC signals at a B_{z} sensitive point (B_{z}=−35 G and Bₓ=−100 G) when the sample is in the mixed state respectively; FIG. 9g and FIG. 9h are DC and AC signals at an Bₓ sensitive point (B_{z}=0 G, Bₓ=360 G) respectively;

FIGS. 10a-10b represent a profile of Bₓ(a),B_{z}(b) along a line perpendicular to the wire that passes by its center for two different currents; and

FIG. 10c is a plot of the intensity of the signal with respect to the current passing through the wire for Bₓ and B_{z}.

### DETAILED DESCRIPTION OF EMBODIMENTS

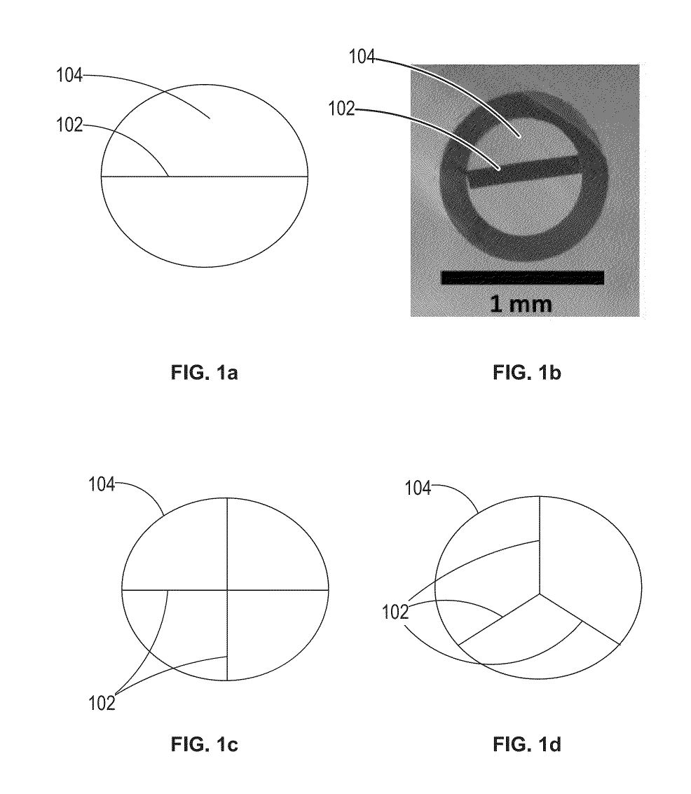

The present invention provides a sensor device comprising a probe carrying a three-dimensional magnetic field sensor. The probe has a conical tip portion with an edge being configured as the three-dimensional magnetic field sensor by which the probe, when in operation, directly approaches the surface of a sample. The sensor at the edge of the tip comprises at least three junctions, each junction being formed by a superconducting layer separated by a barrier. The barrier may be made of a non-superconducting material or may have defined regions of weaker superconductivity obtained by imposing geometrical constrictions. Reference is made to FIGS. 1a-1d showing specific and non-limiting examples of different possible cross sections of the tip of the three-dimensional sensor device having an edge with a closed-loop basis. The conical tip portion forms a structure having at least one arc-like part 102 crossing the opening of the tip portion such that the edge has a closed-loop basis 104 and a plurality of facets defined by the arc-like part 102 forming a three dimensional structure.

In some embodiments, the sensor has one arc-like part crossing the opening of the tip portion such that the edge has two facets and the cross-section of the edge forms a θ-shape as illustrated in FIGS. 1a-1b. FIG. 1b is an optical microscope image of a tip with a θ cross-section, before being pulled to sub-micron dimension. The specific cross-section is defined by a glass separation that goes along the tube.

In other embodiments, the sensor has two arc-like parts crossing the opening of the tip portion such that the edge has four facets forming a three-dimensional square pyramid shape/structure as schematically illustrated in FIG. 1c.

In other embodiments, the sensor has three arc-like parts crossing the opening of the tip portion such that the edge has three facets forming a three-dimensional tetrahedron shape as schematically illustrated in FIG. 1d.

In some embodiments, the invention provides a three-dimensional SQUID fabricated on the edge of a tip being capable of measuring both in-plane and out-of-plane fields.

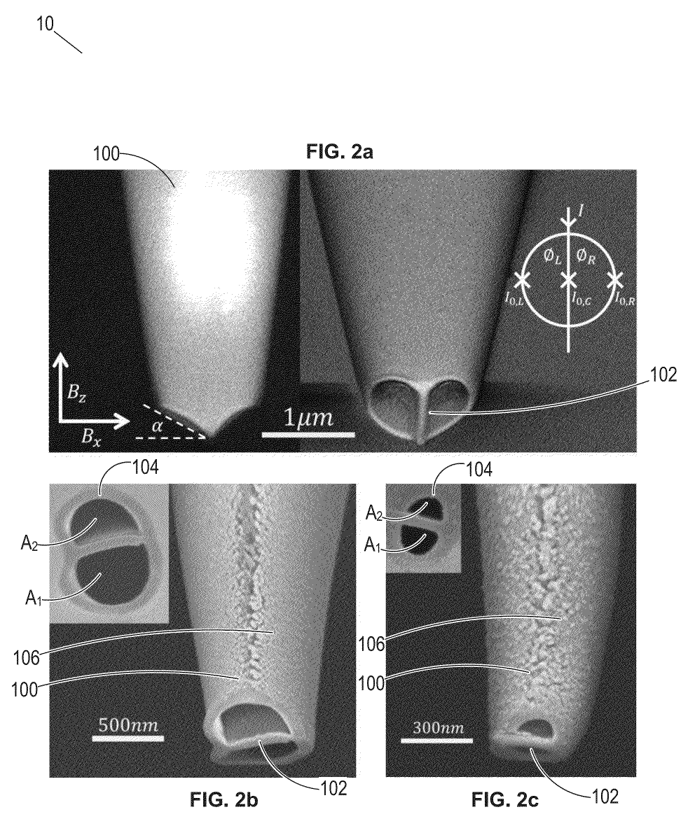

In a specific and non-limiting example, the three-dimensional sensor device of the present invention may be fabricated as follows: a tube is first heated and pulled to sub-micron dimensions. Capillaries made of borosilicate glass may be used with a cross section having at least one arc. It should be noted that tubes with various cross-sections are commercially available, and that laser-induced tube pulling is a standard technique executed with commercially available equipment. For example, 0-shaped capillaries having an outer diameter of 1 mm and inner diameter of 0.7 mm may be used. The capillary may be heated by a heating source such as a laser and subsequently pulled to form at least two tips with sharp apex/edge, while preserving its almost circular contour and the shape of the arc crossing the circular contour. The final size of the edge is controlled by the pulling parameters, and can have an overall diameter as small as 50 nm or even smaller. Contacts can be evaporated along the tube. In a specific and non-limiting example two 200 nm thick Au-based contacts are evaporated along the tube, using a designated mask that prevents them from touching each other and forming an electrical short. In some embodiments, the edge of the tip is milled to a V shape at some desired angle, so that the arc portion (e.g. central partition) protrudes forward as illustrated for example in FIG. 2a. To this end, the tips may be subjected to a Focused Ion Beam (FIB) nano-machining process in an FIB/SEM Dual Beam Microscope.

In a specific and non-limiting example, the tip processing of a tip having one arc crossing its opening may be carried out as follows:

1. The tip is positioned in a vacuum chamber normal to an ion beam direction and the edge is brought to the eucentric point (i.e. where the electron and ion beams coincide) while keeping the central partition of the θ aligned with respect to the ion beam.

2. On a snapshot image of the FIB, the milling segments are specified to obtain the V shape cut and a milling beam, having 7-12 nm in diameter, is activated.

3. The resulting cut is inspected by another FIB snapshot and by a Scanning electron microscope (SEM) beam (giving a complementary image from a different point of view, tilted by 52° with respect to the FIB), and corrected if necessary.

For a three or four facets configuration, three or four different cuts should be applied by using a milling technique. Each cut is carried out at a different angle, adjusted by the rotation of the conical tip about its own axis, forming a tetrahedron or a square pyramid shape/structure at the apex.

Reference is made to FIGS. 2a-2c showing scanning electron microscope images of a tapered θ-tip and of the three-dimensional structure according to some embodiments of the present invention. FIG. 2a is a SEM image of an example of the sensor device 10 of the present invention before deposition of the superconducting layer. In this specific and non-limiting example, a bare borosilicate 0-tip after pulling and ion-milling is represented. The inset shows a schematic diagram of the cross-section of the structure of the three-dimensional sensor device, where X marks represent locations of the Josephson junctions. FIG. 2b shows an example of the structure of the three-dimensional sensor device having an effective loop dimension (i.e. surface area of the loops as derived from the interference pattern) of A=0.45 μm² (A1=0.27 μm² and A2=0.18 μm²). In this example two Pb superconducting electrodes are evaporated and the barrier 106 that forms the side junction is clearly seen. FIG. 2c is another example of the structure of the three-dimensional sensor device having an effective loop dimension of A=0.077 μm² (A1=0.04 μm² and A2=0.037 μm²). It should be noted that the effective loop dimension determines the limit on spatial resolution which can be obtained by magnetic imaging with the device. The effective loop dimension of the device of the present invention is approximately 10 times smaller as compared to conventional SQUIDs. Due to this fact and to the configuration of the device, in which the sensor directly approaches the sample and the junction is located at the apex of the tip, significantly higher spatial resolution is provided.

The present invention provides a sensor device 10 comprising a probe 100 carrying a three-dimensional magnetic field sensor, the probe 100 having a conical tip portion with an edge being configured as the three-dimensional magnetic field sensor by which the probe when in operation directly approaches a surface of a sample. The sensor at the edge of the tip comprises at least three Josephson junctions; each being formed by a superconducting layer separated by a barrier. The barrier may be made of a non-superconducting material or by geometrical constrictions. It should be understood that a SQUID generally comprises a superconducting loop separated by two Josephson junctions. The junctions can be realized by an insulator (SIS) or normal metal (SNS) layer, or by geometrical constriction (Dayem bridge). The sensor has a core made from a non-superconducting material. In some embodiments, the non-superconducting material may be an insulator material such as glass in a non-limiting example. In this specific and non-limiting example, the conical tip portion has at least one arc-like part 102 crossing the opening of the tip portion such that the edge has a closed-loop basis 104 and two facets defined by the arc 102 forming a three-dimensional configuration.

In the figure, the magnetic field orientation is denoted as Bₓ and B_{z} and the tapering angle is denoted is a. In some embodiments, the edge of the conical tip portion is V-shaped with a tapering angle denoted as a in the figure. The tapering angle α is selected such that the arc-like part 102 protrudes forward towards the surface of the sample.

As explained above, the geometry of the structure of the three-dimensional sensor device requires the formation of at least two superconducting layers/electrodes that are separated by a barrier (e.g. non-superconducting layer or an insulating barrier) and overlap the evaporated electrodes. The overlap is required in order to establish electrical contact between the SQUID-on-tip and the measurement circuit via the electrodes. Subsequently, a superconducting layer has to be deposited on the cross section of the structure of the three-dimensional sensor device. The superconducting layer may have a ring-like shape having narrow parts due to the barrier between the two contacts/leads forming the Josephson junctions of the SQUID. In the three-dimensional sensor device, an additional Josephson junction is formed by the presence of the arc 102 crossing the opening of the tip.

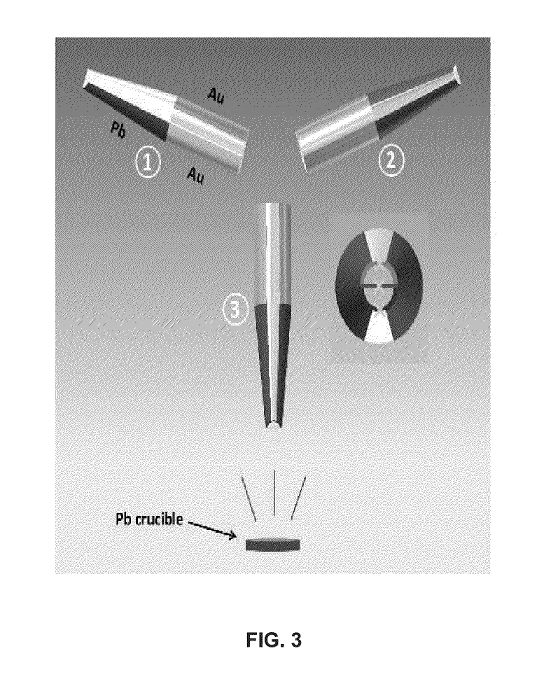

To realize the sensor device, a self-aligned deposition scheme including in-situ rotation [1] has been developed as illustrated in FIG. 3. FIG. 3 is a schematic diagram of a specific and non-limiting example of a three-step deposition scheme applied to fabricate the structure of the three-dimensional sensor device according to one embodiment of the present invention. In this specific and non-limiting example, the superconducting layer is evaporated on the side contacts in steps 1 and 2, and on the circular part (bottom part) in step 3. In this example, Pb-based layers are evaporated on the side contacts forming the electrodes and on the circular part. As shown in the figure, a conducting (e.g. gold) material is evaporated before the evaporation of superconductor-based layers on the upper part of the tubes. The inset shows a point of view projected from the edge of the structure of the three-dimensional sensor device, stressing out the SQUID geometry of the three-dimensional sensor device (where the X marks stand for the Josephson junctions). In particular, in this specific and non-limiting example, in the first and second steps, the 0-tip is tilted in ±110° respectively, and 15-18 nm thick Pb layers are evaporated on the sides, forming the electrodes. On the third step, a 10-12 nm thick layer of Pb is evaporated on the edge to form the ring. In this example, during all the three steps, the average deposition rate was 0.5 nm/s. This scheme requires careful design of a suitable tip holder and proper adjustment in the thermal evaporator.

The high surface mobility of the superconducting layer induces island growth and poor adhesion. This in turn prevents the creation of thin uniform find necessary for the formation of the leads and ring. To overcome this problem a technique for thermal evaporation in cryogenic temperatures has been developed.

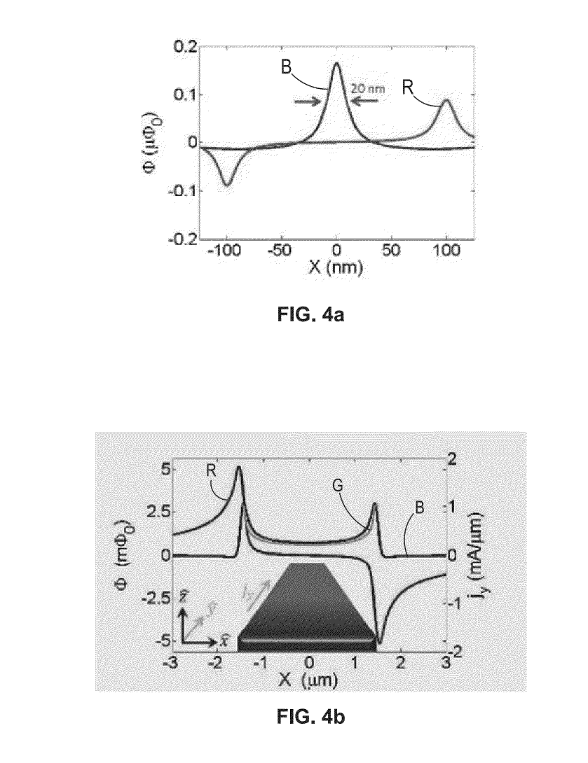

The operation principle of the three-dimensional sensor device is based on the following: the geometric configuration of the three-dimensional sensor device having at least one arc crossing the opening of the tip provides a multiple-loop design making the device responsive not only to the flux threading each loop, ΦL and ΦR (as denoted in FIG. 2a), but also to their sum and difference, Φ⁺=ΦL+ΦR and Φ⁻=ΦL−ΦR. In addition, the novel three-dimensional structure of the sensor device associates Φ⁺ to the out-of-plane field, denoted by Bz, and Φ⁻ to the in-plane field, denoted Bx. Therefore, there is provided a gradiometric device sensitive to the flux difference. Reference is made to FIGS. 4a-4b showing a calculated flux coupled to the three-dimensional double-loop sensor device and to a two-dimensional single-loop device for the sake of comparison due to an in-plane oriented electronic spin (4a) and transport current in a superconducting slab (4b), as a function of horizontal distance.

FIG. 4a shows the imaging of an in-plane oriented single spin in which a single-loop flux response of a two-dimensional device, corresponding to the out-of-plane field Bz, results in two peaks at ±100 nm (R curve), whereas the flux difference response of the three-dimensional sensor device, corresponding to the in-plane field Bx, results in a single, centered peak with width of 20 nm and a factor of two in the signal (B curve). For the purpose of the calculation, the in-plane spin is located at X=0, assuming distance from the sample of d=10 nm. The sensitivity to the normal magnetic flux density lines Bz dictates that the coupling is strongest where the sensor device circumference is right above the spin [3]. This nontrivial response function requires a deconvolution procedure that may degrade the spatial resolution. On the other hand, sensitivity to the in-plane field Bx conveniently implies strongest response when the SQUID is centered right above the spin. Therefore, tuning the three-dimensional sensor device to be mainly sensitive to the flux difference Φ⁻, contributed by the in-plane field, enhances the resolution. Moreover, this combination of flux accumulates opposite signs for ΦR and ΦL, thus giving rise to twice the signal in Φ⁻ for the same overall diameter, as demonstrated by the figure.

To study the distribution of a local transport current, a thin sample carrying an inhomogeneous sheet current density in the ŷ direction, J_{y}(x) is considered. The contribution to the in-plane field Hₓ(x₀) due to a current element at x₀ is J_{y}(x₀)/2 dx, thus, at close proximity to the surface Bx(x) is proportional to the local current density. As opposed to that, the local current density contribution to the out-of-plane field Bz(x) vanishes, giving rise to a non-local dependence. FIG. 4b shows a measurement of a transport current in a superconducting slab in the Meissner state [4]. The current density can be extracted from the in-plane field in a straightforward manner, whereas existing scanning probe techniques, which currently measure only the out-of-plane field, require elaborate nonlocal inversion schemes.

This is illustrated on FIG. 4b, which shows flux (R curve) and flux difference (B curve) response to current density distribution j_{y}(x) (G curve, secondary axis) calculated at a cross section of a superconducting slab in the Meissner state. The flux response exhibits pronounced non-local contributions and is non-vanishing only near the edges of the sample, whereas the flux difference offers indication for the local current density. Both the two-dimensional device and the three-dimensional sensor device have an overall diameter of 200 nm and the scanning distance is 10 nm.

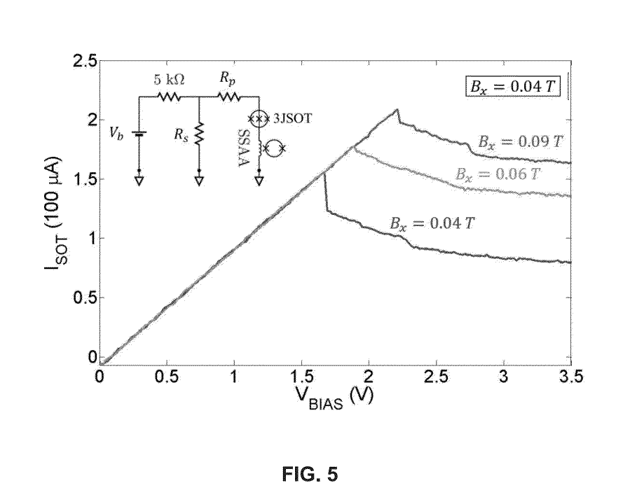

The inventors used a SQUID Series Array Amplifiers (SSAA) to measure the current in the three-dimensional sensor device. In this specific and non-limiting example, the SSAA was used as a cryogenic, low-impedance current-to-voltage con-vertor for the current comprising a hundred Nb SQUIDs connected in series, which are inductively coupled to the three-dimensional SQUID sensor and to a feedback coil. A change in the current of the three-dimensional sensor device induces a change in the magnetic flux of the SSAA and in its critical current and voltage accordingly, which is amplified by a pre-amplifier box. The SSAA was operated in a flux-locked loop mode (FLL). The operation of the three-dimensional sensor device is based on a quasi-voltage bias configuration. Reference is made to FIG. 5 representing schematics of an example of a possible measurement circuit and several IV curves at different Bₓ filed biases at constant B_{z}=0.03T. The critical current corresponds to the maximum and is followed by the negative differential resistance regime. The inset shows schematics of the measurement circuit. The shunted SQUID is current biased by sweeping the applied voltage Vb connected in series to a cold Rb\tilde{=}5 kΩ resistor up to the critical current when the normal state starts to form. As the SQUID becomes resistive, current flows also through the shunt resistor Rs\tilde{=}5 kΩ, and as the SQUID resistance increases, it becomes effectively voltage biased. The current of the three-dimensional sensor device is converted and amplified by the SSAA which is inductively coupled to the three-dimensional sensor device. The amplified signal is fed into a feedback circuit and a voltage V_{FB} is supplied to the feedback coil in order to compensate for the change, so that V_{FB} is proportional to the current from the three-dimensional sensor device. Once the current starts to flow through the shunt resistor, one detects decreasing V_{FB}, and thus a maxima in the IV curve corresponding to the critical current of the three-dimensional sensor device. The decreasing current in the three-dimensional sensor device for increasing Vb results in a negative differential resistance, which is necessary for imaging purposes.

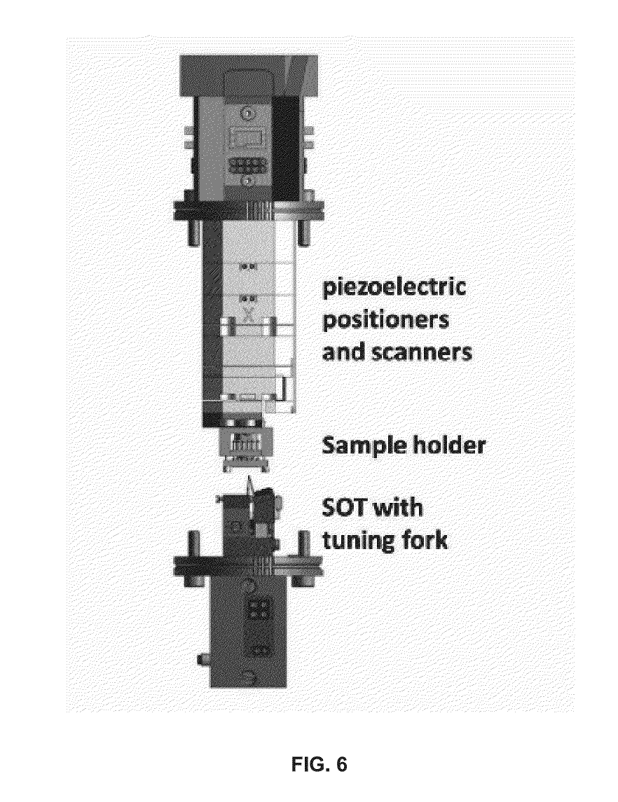

The inventors of the present invention have also developed a 4K Scanning SQUID Microscope (SSM) adjusted to be integrated with the three-dimensional sensor device. Reference is made to FIG. 6 representing a schematic view of the SSM assembly. The SSM also incorporates atomic force microscopy (AFM) abilities when a tuning fork is attached to the tip (denoted in the figure as SOT-SQUID ON TIP). The microscope resides in a vacuum cap at the bottom of a rod, to be inserted into a Helium dewar, and various electrical connectors are wired through the rod to its top part. A stack of commercial Attocube piezoelectric coarse positioners and scanners enables three-dimensional positioning with nanometric precision within a volume of the order of a few mm. The sample holder is connected at the bottom of the positioner stack. It incorporates, in addition to the chip carrier with electric contacts, a calibrated Lakeshore diode and a heater for temperature control of the sample. In this design, the sample is moved with respect to the stationary tip. The three-dimensional sensor device is situated opposite the sample at the bottom part of the rod. This part also holds the electronics required for the tuning fork operation.

In order to inspect the properties of the sensor device of the present invention, numeric simulations were carried out. The first goal was to reconstruct the interference pattern of the critical current I_{c} of the new device. In order to do that, the DC Josephson relation I=I_{c} sin (δ) was generalized to the three-junction case, (δ is the superconducting order parameter phase difference across the junction. By considering each sub-loop as a separate SQUID, penetrated by a total flux which is the sum of the applied flux and the flux induced by the circulating current, the following is obtained (1):

$${δ}_{L} - {δ}_{C} = \frac{2 π}{{∅}_{0}} ( {∅}_{L}^{a} - {L}_{L} {I}_{0 , L} sin {δ}_{L} + {L}_{C} {I}_{0 , C} sin {δ}_{C} )$$

$${δ}_{C} - {δ}_{R} = \frac{2 π}{{∅}_{0}} ( {∅}_{R}^{a} - {L}_{C} {I}_{0 , C} sin {δ}_{C} + {L}_{R} {I}_{0 , R} sin {δ}_{R} )$$

The subscripts L, R and C denote respectively the left, right and central arm of the sensor device. Φ^{a} is the applied flux, δ is the phase difference across the junction, I₀ is its critical current and L is the inductance.

The total current is given by (2):

Iₜₒₜₐₗ=I_{0,L} sin δ_{L}+I_{0,C} sin δ_{C}+I_{0,R} sin δ_{R}

Upon setting Φ_{L}^{a} and Φ_{R}^{a}, (1) is used to eliminate two phases from (2) and then find the maximal Iₜₒₜₐₗ which defines the sensor device I_{c}. It is constructive to define the flux sum Φ⁺=Φ_{L}^{a}+Φ_{R}^{a} and difference Φ⁻=Φ_{L}^{a}−Φ_{R}^{a}, which are the significant physical quantities in this configuration. The resulting pattern I_{c} (0⁺, Φ⁻) is a periodic lattice of triangular peaks, where their exact shape depends on the critical current and inductance parameters of the junctions. As in the standard SQUID case, the critical current affects the amplitude of the modulation, whereas the inductance mainly governs its depth. This pattern can be modified by asymmetry factors in the critical currents and the inductance which are taken into account in the simulations.

To use the sensor device of the present invention as a magnetometer in practice, its geometry should be associated with the applied magnetic fields and represent I_{c} as a function of B_{z} and Bₓ. For a sensor device with tapering angles α=α_{L}=α_{R} (α≠0) and loop effective areas A_{L} and A_{R}, the fields are associated with the flux by the following transformation (3):

$$( \begin{matrix}{B}_{z} \\ {B}_{x}\end{matrix} ) = \frac{1}{{A}^{2} ( 1 - {Δ}^{2} ) sin α cos α} ( \begin{matrix}sin α & - Δ sin α \\ Δ cos α & cos α\end{matrix} ) ( \begin{matrix}{∅}^{+} \\ {∅}^{-}\end{matrix} )$$

Where A=A_{L}+ and

$$Δ = \frac{{A}_{L} - {A}_{R}}{A} .$$

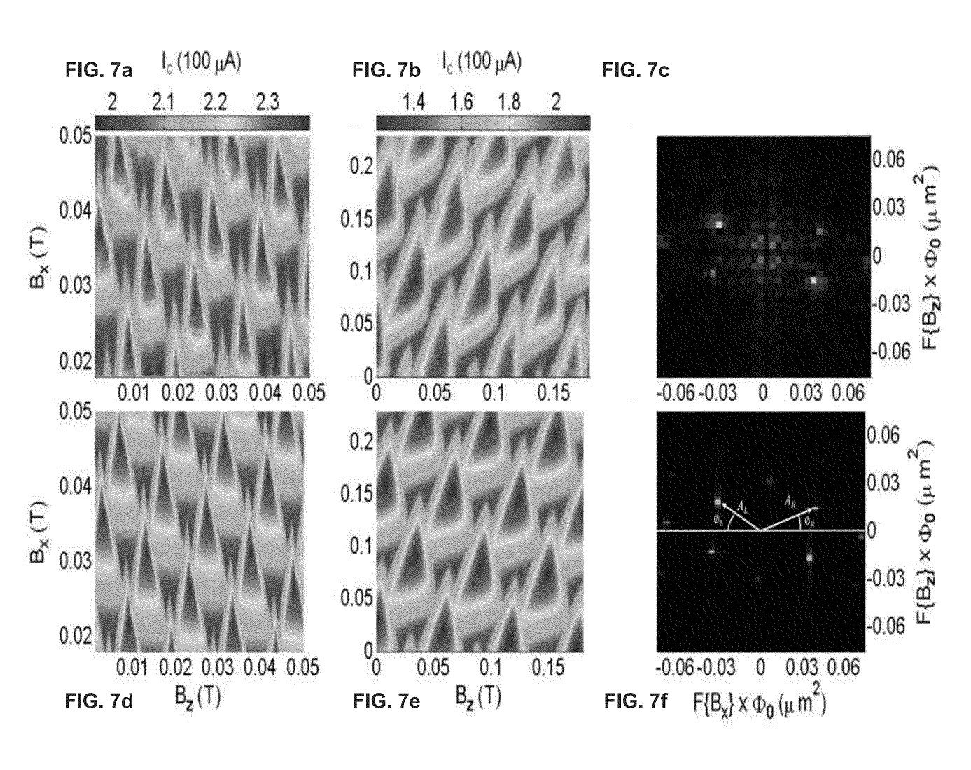

The off-diagonal terms scale like Δ so for a nearly symmetric sensor device (Δ<<1) B_{z} corresponds, up to a factor, to Φ⁺ and Bₓ corresponds to Φ⁻, where it is also assumed that the fields do not vary significantly on a scale comparable to the characteristic size of the device. This transformation implies a modification of the interference pattern, subjected to the geometrical parameters A, Δ and α. These parameters show a pronounced impact on the pattern, as they affect not merely the shape of individual peak or add an overall shift, but also modify the structure of the lattice itself, i.e. changing its periodicity and directionality as illustrated in FIGS. 7a-7f. This fact suggests that the geometrical parameters can be extracted from the pattern by 2D Fast Fourier Transform (FFT) with respect to the fields, scaled by Φ₀. This is equivalent to the determination of the effective area of a SQUID from the oscillation period, as verified self-consistently from performing FFT on the simulations (FIG. 7f) and comparing these to SEM images. The FFT is a powerful tool since it is robust against the particular deformation of an individual triangle, and it was used to narrow substantially the large parameter space which can be scanned in order to fit the data, by extracting independently the geometrical parameters. As an example, FFT of the sensor device of FIG. 2c is shown in FIG. 7c, and the derived values are A_{L}=0.04 μm², A_{R}=0.037 μm², a_{L}=19° and a_{R}=27°, in agreement with SEM images.

Reference is made to FIGS. 7a-7f representing an interference pattern obtained by using the novel sensor device of the present invention. In particular, FIG. 7a represents a measurement and FIG. 7d represents a simulation of I_{c}(Bₓ,B_{z}) of the sensor device of FIG. 2b. The orientation of the triangles lattice is determined only by the geometrical structure of the sensor device, whereas the shape of an individual peak may depend also on the critical currents and the inductance of the junctions. FIG. 7b represents a measurement and FIG. 7e represents a simulation of I_{c}(Bₓ,B_{z}) of the sensor device of FIG. 2c. FIG. 7c represents a Fast Fourier Transform (FFT) of FIG. 7b, the exact geometrical parameters can be extracted: A_{L}=0.04 μm², A_{R}=0.037 μm², a_{L}=19° and a_{R}=27°. FIG. 7f represents an FFT of FIG. 7e. The arrow in FIG. 7e indicates the locations of the maxima and the quantities derived from them. FIGS. 7a and 7b show the measured I_{c}(Bₓ,B_{z}) for two different devices with total area of 0.45 μm² and 0.077 μm² respectively (corresponding to SEM images in FIGS. 2b and 2c). For the latter device, the maximal total current is I_{c}=210 μA. The dependence of the modulation depth on the critical current and the inductance was also deduced from the simulations as will be described below. This is equivalent to the two-junction case, where the inductance governs the modulation depth. Thus, knowing the modulation depth −38% in this case, the total inductance—L=45 pH. Fitting the simulations to the data, the sub-loops structure can also be probed. About 50% of the maximal current flows through the central junction, about 40% through one of the side junctions and only about 10% through the remaining junction. The inductance distribution has the opposite trend. The contribution of the central branch to the total inductance is only about 20% and the rest is distributed equally between the two side branches. These findings may indicate that the effective width and thickness of the central Dayem bridge is larger, naturally giving rise to higher critical current. Regarding the inductance, in a device of such small dimensions, it seems to be governed mainly by the kinetic inductance,

$${L}_{k} = \frac{{μ}_{0} {λ}_{L}^{2} l}{wt}$$

where μ₀ is the vacuum permeability, λ_{L} is the London penetration depth, l is the bridge length, t is the film thickness and w is its width. Thus, a wider and thicker structure implies smaller contribution to the total inductance.

The operation of the sensor device is based on a quasi-voltage bias configuration [1]. The shunted SQUID is current biased by sweeping the applied voltage V_{b} connected in series to a cold R_{b}=5 kΩ resistor up to the critical current, when the device starts to switch to its normal state. As the SQUID becomes resistive, current flows also through the shunt resistor R_{b}=1Ω, and as the SQUID resistance increases, it becomes effectively voltage biased. The sensor device current I_{3J} is converted and amplified by the serial SQUID array amplifier which is inductively coupled to the sensor device. The amplified signal is fed into the feedback box and a voltage V_{FB} is supplied to the feedback coil in order to compensate for the change, so that V_{FB} is proportional to I_{3J}. Once the current starts to flow through the shunt resistor, one detects decreasing V_{FB}, and thus a local maximum in the IV curve corresponding to the critical current of the sensor device. The decreasing current in the sensor device for increasing V_{b} results in a negative differential resistance, which varies with the external field at a given V_{b}.

To measure the variation of the field, the sensor device is voltage-biased and the corresponding V_{FB} is measured. Since changes as a function of field, the negative differential resistance part of the I-V curves shifts and in this region V_{FB} becomes a function of the field. Biases where this function is smooth and linear as sensitive points are considered and the sensitivity is defined as

$$\frac{Δ {V}_{FB}}{Δ B} .$$

To realize a practical vector magnetometer out of the sensor device, decoupling of the response function to in-plane and out-of-plane fields must be feasible. One approach would be to apply such external magnetic fields and voltage bias at which the gradient is large in one direction and vanishes in the other, i.e. where the contour lines in the I_{c}(Bₓ,B_{z}) plot are parallel to one of the axes. To gain a more quantitative measure, it is convenient to define the decoupling ratio in the vicinity of a working point:

$$\frac{Δ {V}_{FB}}{Δ {B}_{i}} / \frac{Δ {V}_{FB}}{Δ {B}_{j}} ,$$

with i,j=x, z. It is self-evident that properties of such a decoupling regime are subjected to the specific details of the interference pattern, which can be manipulated to some extent in the fabrication process. Alternatively, to reduce this restrictive dependency on the specifics of the device, a different approach can be adopted. Acquisition of the response in two different applied fields' configurations, which results in two linearly independent gradients, can be used to diagonalize the signal. Namely, the in-plane and out-of-plane image can be reconstructed as a linear combination of two mixed signals, measured at predetermined working points.

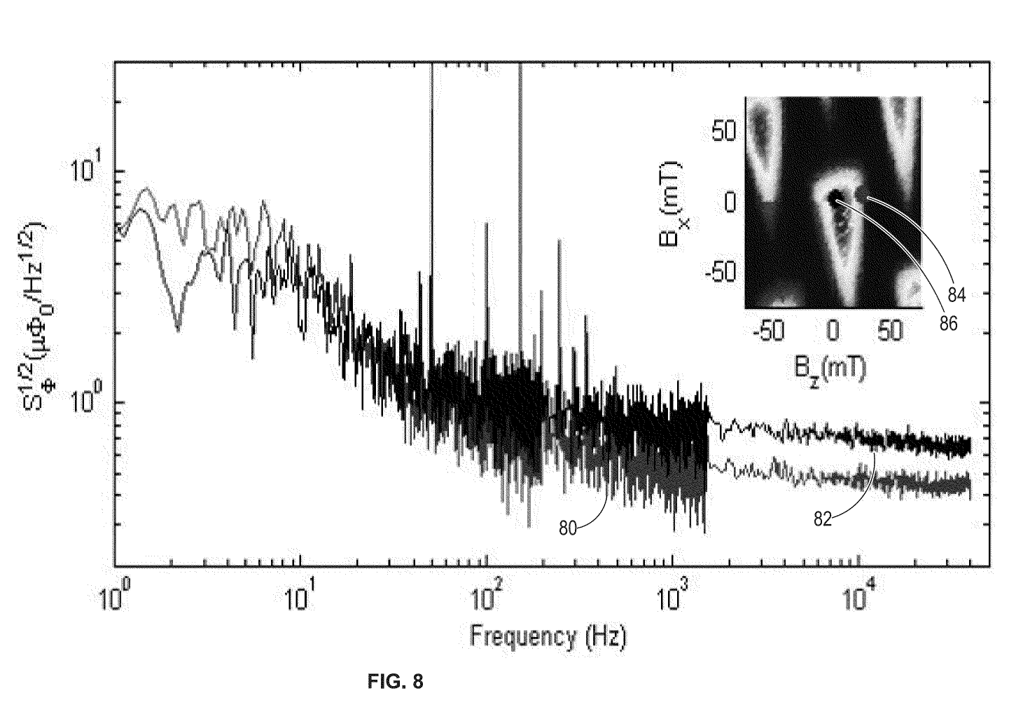

To determine the typical signal-to-noise ratio and bandwidth of the sensor device of the present invention, a systematic noise characterization of the sensor device was conducted, later used for scanning Reference is made to FIG. 8 showing the spectral noise density of the sensor device at Bₓ and B_{z} sensitive points determined by the interference pattern (inset). FIG. 8 represents field noise spectra of a sensor device at the working point sensitive to the in-plane and out-of-plane field for a sensor device having an effective loop dimension of 0.06 μm² at 4.2 K. The spectral field noise density (SB^{z}) 80 for a working point sensitive to the out-of-plane field (V_{Bias}=2 V, B_{z}=242 G, Bₓ=50 G). The spectral field noise density (S_{B}^{x}) 82 for a working point is sensitive to the in-plane field (V_{Bias}=2.338 V, B_{z}=25 G, Bₓ=23 G). The inset of the figure represents a measured I_{c}(Bₓ,B_{z}) around the working regions used for scanning. The color scale is 180 μA to 240 μA. The dots 84 and 86 show the working point selected to measure the spectra, where the B_{z} (Bₓ) is effectively decoupled. At the Bₓ sensitive point the decoupling ratio is about 10 and at the B_{z} sensitive point it is about 30, with dynamic working range of few tens of Gauss. The noise profile consists of 1/f noise that changes after a few hundreds of Hz into white noise smaller than S_{B}^{x}=0.7 mG/Hz^{1/2} and S_{B}^{z}=0.2 mG/Hz^{1/2} for the Bₓ and B_{z} sensitive points respectively.

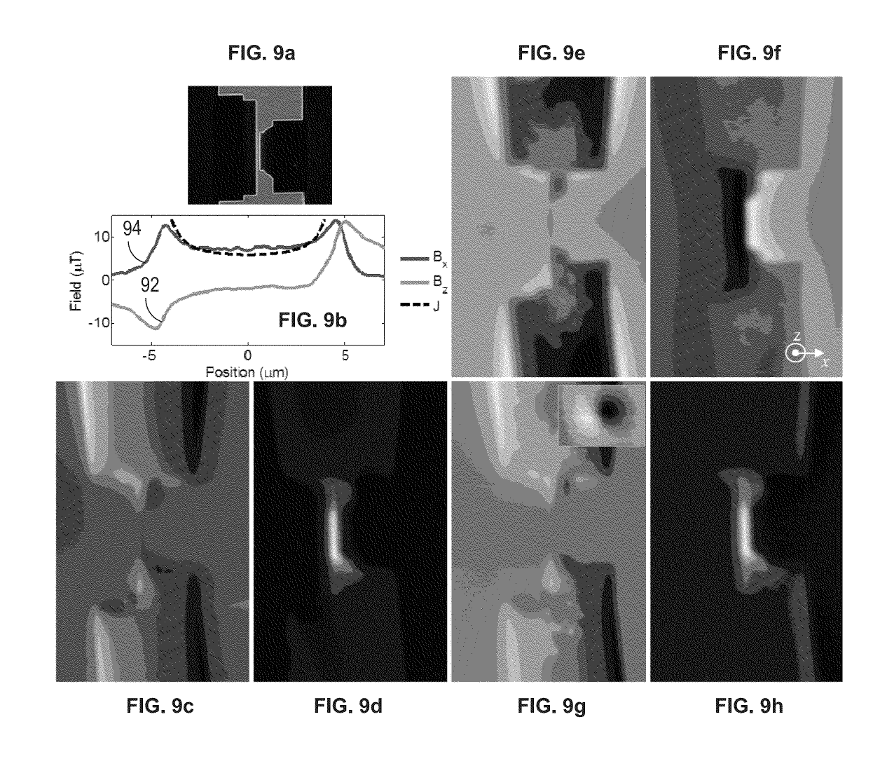

The sensor device was integrated into an in-house-built scanning microscope, operating at 4.2 K. As a proof of concept, both components of the field generated by a superconducting nanostructure were measured. Measuring a superconducting sample introduces some complications to the method since the local field can vary considerably from the applied field. As a result, different working points were reacquired when getting in-range with the sample. Reference is made to FIGS. 9a-9h representing images of a Pb wire as will be detailed below. In particular, FIG. 9a is a SEM image of a 0.35×4 μm² Pb wire and FIG. 9b shows the fields' profiles measured on a linecut across the sample for the in-plane B_{z} (92) and out-of-plane Bₓ (94) components. The dashed line noted in the figure as J shows the local current distribution near the tip. It can be noted that the Bₓ component 94 fits to the local current distribution J. FIGS. 9c-9h are sensor device scanning microscopy images. More specifically, FIGS. 9c and 9d are DC and AC signals at a Bₓ sensitive point (Bₓ=320 G, B_{z}=0 G) respectively, when the sample is in the complete Meissner state. FIGS. 9e and 9f are DC and AC signals at a B_{z} sensitive point (B_{z}=−35 G and Bₓ=−100 G) respectively, when the sample is in the mixed state. FIGS. 9g and 9h are DC and AC signals at a Bₓ sensitive point (B_{z}=0 G, Bₓ=360 G) respectively; in these conditions the sample should be free of vortices. However, this frame was taken after FIGS. 9e and 9f, keeping the previously induced vortices in the sample. The field of view in all images is 24×16 μm². The inset in FIG. 9g is a 3×4.2 μm² image of a single vortex. The dark-to-bright scales are as follows: FIG. 9c 108 G; FIG. 9d −15.8 to 695 mG; FIG. 9e 142 G; FIG. 9f −305 to 359 mG; FIG. 9g 140 G; FIG. 9h −68 to 563 mG.

The sample shown in FIG. 9a consists of a 100 nm thick Pb layer deposited on a Si substrate at about 77 K. To avoid oxidation, the Pb layer was coated in-situ with a 10 nm Ge layer. An 8 μm wide strip is first patterned using standard lithography, and further FIB patterning is used to obtain a 350 nm by 4 μm wire.

While scanning, a 10.372 kHz current is passed through the wire. The AC signal measured by the sensor device is acquired using a lock-in amplifier set at the same frequency as the transport current and the DC signal is recorded simultaneously. FIGS. 9c and 9d show the Bₓ component of the signal when the sample is in the Meissner state in an applied field of Bₓ=320 G and B_{z}=0 G. As discussed above, the Bₓ component of the field gives direct information on the local current distribution near the tip. Consequently, the DC signal (FIG. 9c) reveals the Meissner current distribution flowing in opposite directions along each edge and screens the applied field. This appears in the image as a field of +50 G on the right side of the bridge and −50 G on the left side of the bridge which indicates that the Meissner current flows in opposite direction on each edge of the bridge. The AC signal (FIG. 9d) reveals the Biot-Savart field generated by the injected currents. This image explicitly demonstrates the advantage of measuring the Bₓ component, as it directly indicates the flow of the transport current only along the edges (see FIG. 4b and FIG. 9b). In particular, this current distribution is remarkably resolved even as the strip narrows to sub-micron dimensions. Only in the constriction itself, where the characteristic dimensions are of the order of the sensor device size, the current density cannot be resolved and appears uniform. The variation in B_{z} at applied external fields B_{z}=−35 G and Bₓ=−100 G was probed. In these conditions, the sample is in a mixed state where vortices and Meissner current coexist. The DC signal of the B_{z} component (FIG. 9e) shows a higher field profile (dark spots) of about 15 G where a vortex is located. The AC signal (FIG. 9e) has a zero-crossing right above the wire and finite values beside it, where no current is flowing (see FIG. 4b). As a result, reconstructing the current distribution from the B_{z} component of the field involves sophisticated calculations which require to map out the field of the entire sample to ensure convergence to a unique solution. After acquiring this image it is possible to image a similar mixed state in an Bₓ sensitive point by reducing the B_{z} field to 0 and increasing Bₓ to 360 G. The Meissner currents are again visible (FIG. 9g), but the vortices now appear as a mixture of high and low fields, exhibiting an antisymmetric field profile (inset). Such a profile gives less clear information regarding the position of the vortex and is therefore not preferable for vortex imaging. These two examples, flow of currents in a sample and monopole-like objects such as vortices, show the advantages of being able to measure simultaneously both the in-plane component in the former case and out-of-plane component in the latter. Therefore, the results presented in FIGS. 9a-9h demonstrate that the capabilities of the sensor device of the present invention to provide a scanning measurement technique which was implemented successfully to a sample, overcoming all the technical difficulties it involves.

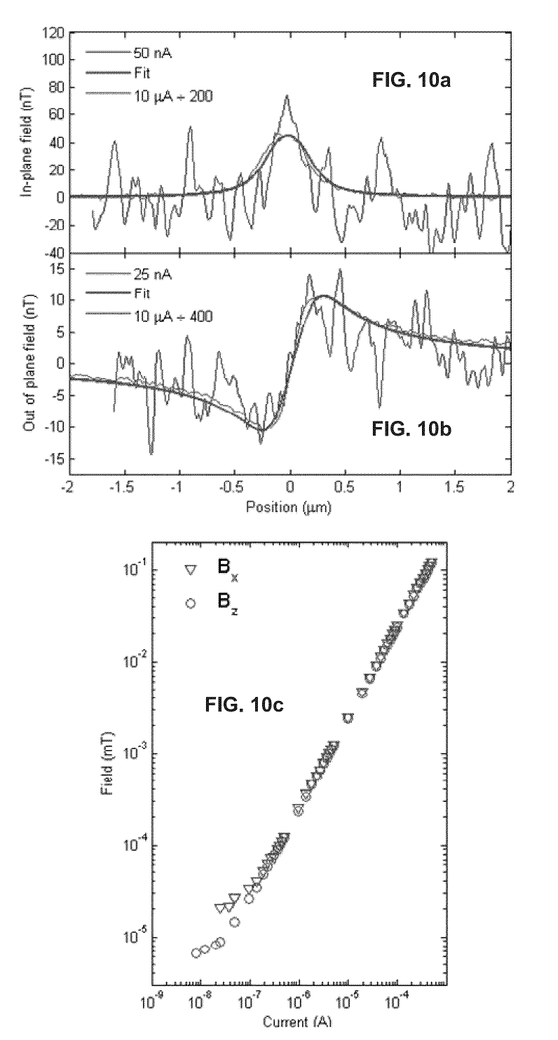

To quantify the decoupled fields' measurement and to estimate the sensitivity limits of the sensor device, the field profile over a line-cut across the wire was measured. An integration time of 1 s was set to be consistent with the noise analysis shown above. Reference is made to FIGS. 10a-10c representing a field profile in the center of the wire, the profile of Bₓ(a), B_{z}(b) along a line perpendicular to the wire that passes by its center for two different currents. In particular, in FIG. 10a the current applied was 50 nA and 10 μA. The field applied was B_{z}=0 G Bₓ=370 G. In FIG. 10a, the current applied was 25 nA and 10 μA. The field applied was B_{z}=+250 G Bₓ=−100 G. Low currents are scaled for the sake of visualization. FIG. 10c represents a plot of the intensity of the signal with respect to the current passing through the wire for Bₓ and B_{z}. The dashed line indicates the calculated sensitivity from FIG. 8 for Bₓ and B_{z}. The field profiles for both field components are shown in FIGS. 10a-10c for a relatively large current (10 μA) and for a small yet detectable current (50 nA). The data was fitted to the theoretically calculated current (represented in the figure as Fit curve) and obtained good agreement, which proves that the two components of the field were effectively decoupled. The distance is kept as a fitting parameter, which gives a scanning distance of about 140 nm from the sample.

The profiles were measured for a wide range of currents ranging from 500 μA to 10 nA. The measurements are summarized in FIG. 10c where the maximal value of the measured field is plotted as a function of the injected current. The dashed lines indicate the noise level calculated from the noise spectrum of FIG. 8, and below this threshold the points no longer fall on a straight line, consistent with the previous noise estimation. For B_{z}, where the field sensitivity is about 4 times better than Bₓ, the lowest detectable current is 25 nA, which is only a factor of 2 better than the lowest detectable current when Bₓ is measured. This is due to the coupling of Bₓ to the sensor device which is a factor of 2 higher, resulting in an improved signal to noise ratio.

Therefore, the sensor device of the present invention demonstrates a tunable response to both in-plane and out-of-plane fields, while meeting the size and sensitivity standards of state of the art nano-SQUIDs. This versatile tool opens a door to nanoscale magnetic imaging possibilities which were inaccessible thus far.

What is claimed is:

1. A sensor device comprising a probe carrying a three-dimensional magnetic field sensor, the probe having a conical tip portion with an edge being configured as said three-dimensional magnetic field sensor by which the probe when in operation directly approaches a surface of a sample, said conical tip portion forming a tapered three-dimensional structure such that said sensor has at least one arc-like part crossing the opening of the tip portion such that said edge has a closed-loop basis and a plurality of complimentary spaced-apart facets defined by said at least one arc-like part; said sensor at the edge of the tip comprising at least three junctions, each junction being formed of a superconducting layer which is interrupted by a barrier; said barrier comprising a non-superconducting layer or a geometrical constriction.

2. The device according to claim 1, wherein said sensor is configured as a Josephson junction based sensor.

3. The device according to claim 1, wherein said sensor comprises a SQUID (Superconducting Quantum Interference Device) loop extending along a circumferential region at the edge of the conical tip portion.

4. The device according to claim 1, wherein the edge of said conical tip portion is tapered with a defined tapering angle.

5. The device according to claim 1, wherein said conical tip portion is configured such that the arc-like part protrudes forward towards said surface of the sample with respect to side junctions that reside along the closed-loop basis.

6. The device according to claim 1, wherein said sensor has one arc-like part crossing the opening of the tip portion-forming a double-loop structure such that the edge has two facets and the cross-section of the edge forms a 0-shape with V-shaped profile hence-forming said three-dimensional structure.

7. The device according to claim 1, wherein said sensor has two arc-like parts crossing the opening of the tip portion such that the edge has four facets forming a three-dimensional square pyramid structure.

8. The device according to claim 1, wherein said three-dimensional structure has three arc-like parts crossing the opening of the tip portion such that the edge has three facets forming a three-dimensional tetrahedron structure.

9. The device according to claim 1, wherein said conical tip portion has a maximal outer diameter not exceeding a few hundreds of nanometers.

10. The device according to claim 1, wherein said sensor has a core made from non-superconducting material and a superconducting layer coating at least one selected circumferential region of said non-superconducting core forming a plurality of Josephson junctions or geometrical constrictions constituting a multi-junction SQUID structure.

11. The device according to claim 10, wherein said non-superconducting material comprises an electrical insulator material.

12. The device according to claim 1, wherein said superconducting layer is made from a material selected from a group consisting of: aluminum, niobium, lead, indium, and tin-based materials.

13. A method for fabricating a three-dimensional sensor device comprising:
heating and pulling a tube to sub-micron dimensions so that the edge of the tube has a closed-loop basis, having at least one arc-like part crossing the opening of the tube; and milling the edge of the tube to a three-dimensional configuration such that the arc-like part protrudes forward towards a surface of a sample with respect to the side junctions that reside along the closed-loop basis.

14. The method according to claim 13, comprising evaporating at least two contacts along the tube by using a mask configured to prevent an electrical short between the contacts.

15. The method according to claim 13, comprising milling the edge of the tube to a tapered shape.
